(19) United States
(12) Patent Application Publication
(10) Pub. No.: US 2022/0386504 A1
(43) Pub. Date: Dec. 1, 2022

(54) ELECTRONIC DEVICE

(71) Applicant: PEGATRON CORPORATION, TAIPEI CITY (TW)

(72) Inventors: Yaw-Song Chen, Taipei City (TW); Yi-Ming Chou, Taipei City (TW)

(73) Assignee: PEGATRON CORPORATION, TAIPEI CITY (TW)

(21) Appl. No.: 17/706,143

(22) Filed: Mar. 28, 2022

(30) Foreign Application Priority Data
May 31, 2021 (TW) 110206281

(51) Int. Cl. H05K 7/20

(52) U.S. Cl. CPC H05K 7/20145; H05K 7/205; H05K 7/20409; B60L 53/302

(57) ABSTRACT

An electronic device includes a housing, a heat conductive portion, a circuit board, a fin set, and a fan. The housing has an accommodating space. The heat conductive portion is disposed in the accommodating space, and divides the accommodating space into a first space and a second space. The circuit board is disposed in the first space and includes a heat source. The heat source generates heat and is thermally coupled to the heat conductive portion. The fin set is disposed in the second space and thermally coupled to the heat conductive portion. The fan is disposed in the second space and located on one side of the fin set. The fan is adapted to guide an airflow through the fin set to discharge the heat generated by the heat source from the housing.

### CROSS-REFERENCE TO RELATED APPLICATION

This application claims the priority benefit of Taiwan application Ser. No. 110206281, filed on May 31, 2021. The entirety of the above-mentioned patent application is hereby incorporated by reference herein and made a part of this specification.

### BACKGROUND

### Technical Field

The disclosure relates to an electronic device, and more particularly to an electronic device with excellent heat dissipation performance and dustproof effect.

### Description of Related Art

As environmental protection has gradually received attention, innovations have emerged in transportation, and electric vehicles have become popular on the market. Compared with fuel engines, electric vehicles need to be charged for a long time, so the demand for charging stations is gradually increasing.

A conventional charging station mainly uses a fan to directly blow airflow to the circuit board, thereby dissipating heat inside the charging station. However, dust is easy to enter the charging station with the airflow generated by the fan, which will affect the heat dissipation efficiency of the charging station over time, and may cause the charging station to be in a non-conducting state.

### SUMMARY

The disclosure provides an electronic device which has excellent heat dissipation performance and dustproof effect.

The electronic device of the disclosure includes a housing, a heat conductive portion, a circuit board, a fin set, and a fan. The housing has an accommodating space. The heat conductive portion is disposed in the accommodating space, and divides the accommodating space into a first space and a second space. The circuit board is disposed in the first space, and includes a heat source. The heat source generates heat and is thermally coupled to the heat conductive portion. The fin set is disposed in the second space and thermally coupled to the heat conductive portion. The fan is disposed in the second space and located on one side of the fin set. The fan is adapted to guide an airflow through the fin set to discharge the heat generated by the heat source from the housing.

Based on the above, in the electronic device of the disclosure, the heat generated by the heat source is transferred to the fin set through the heat conductive portion, and then the fan guides the airflow through the fin set to discharge the heat from the housing, thereby providing excellent heat dissipation efficiency. In addition, since the heat conductive portion isolates the circuit board from the fin set, the dust entering the fin set with the airflow of the fan will not adhere to the circuit board and the heat source, thereby providing an excellent dustproof effect.

In order to make the aforementioned features and advantages of the disclosure comprehensible, embodiments accompanied with drawings are described in detail as follows.

### BRIEF DESCRIPTION OF THE DRAWINGS

FIG. 1 is a three-dimensional schematic diagram of an electronic device according to an embodiment of the disclosure.

FIGS. 2 and 3 are three-dimensional schematic diagrams of partial components of the electronic device of FIG. 1 in different viewing angles.

FIGS. 4 and 5 are schematic cross-sectional views of a part of the electronic device of FIG. 1.

FIG. 6 is a schematic view of an electronic device according to another embodiment of the disclosure.

### DESCRIPTION OF THE EMBODIMENTS

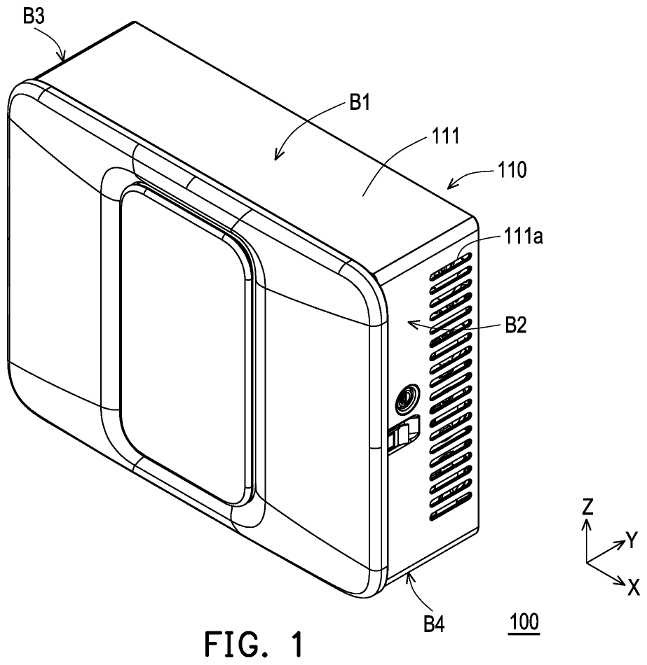

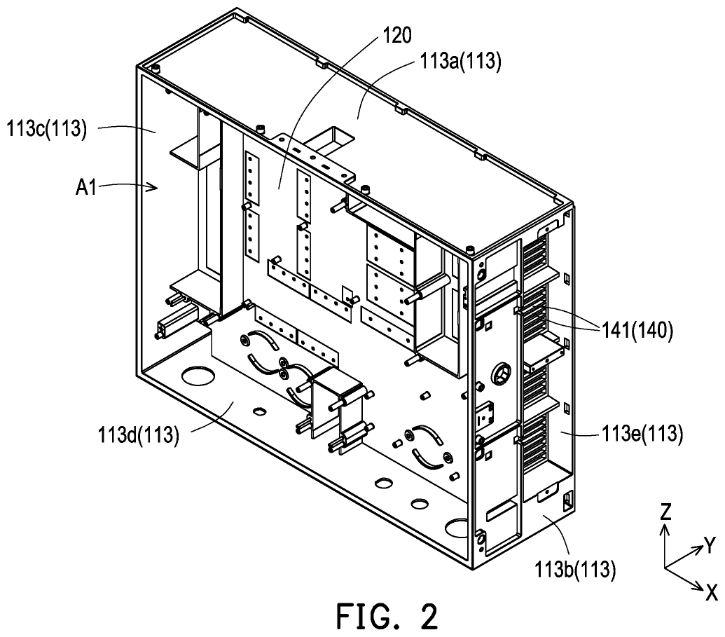

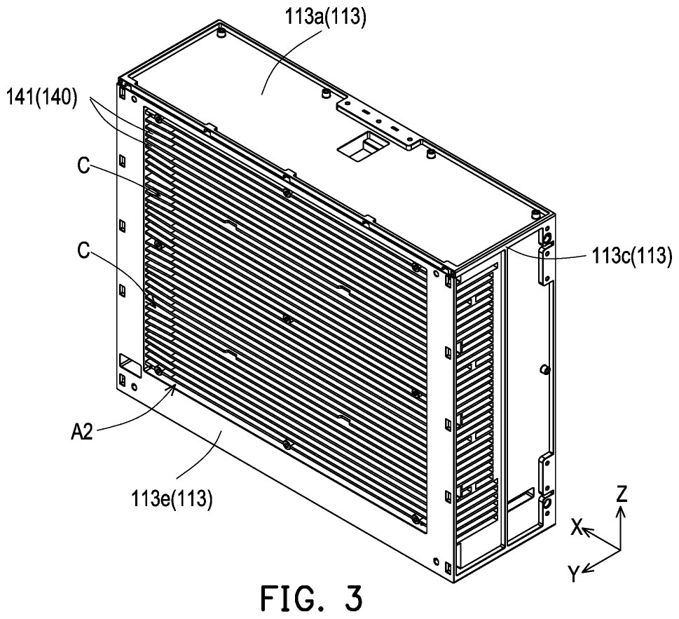

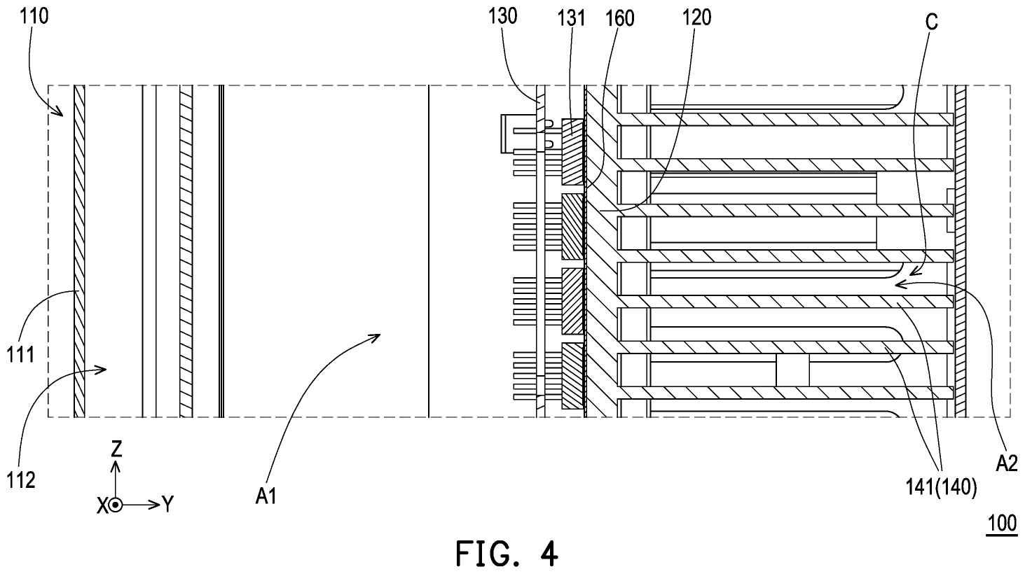

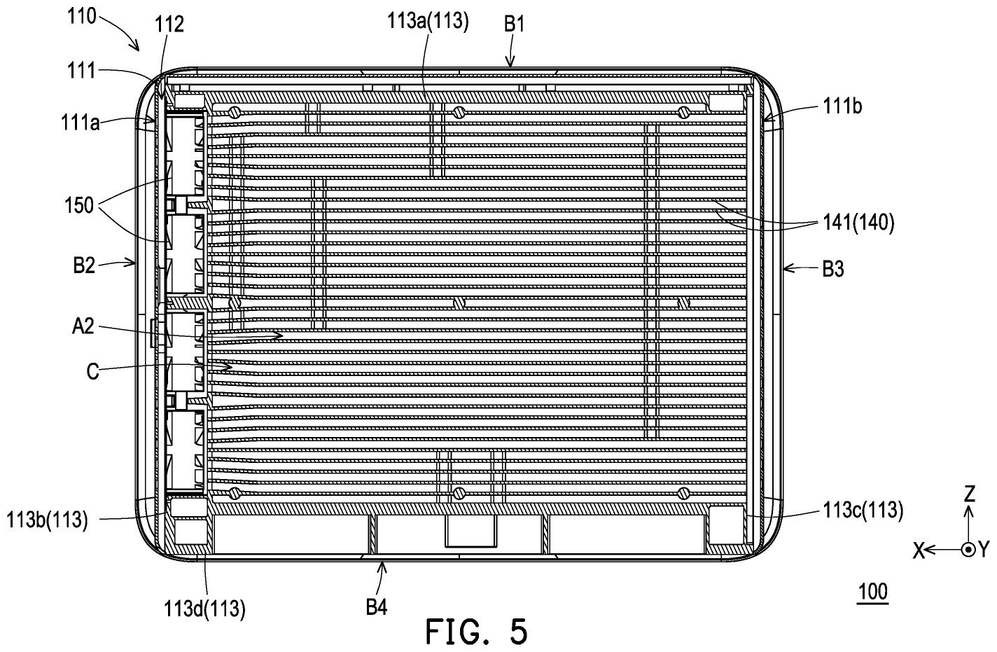

FIG. 1 is a three-dimensional schematic diagram of an electronic device according to an embodiment of the disclosure. FIGS. 2 and 3 are three-dimensional schematic diagrams of partial components of the electronic device of FIG. 1 in different viewing angles. FIGS. 4 and 5 are schematic cross-sectional views of a part of the electronic device of FIG. 1. In particular, coordinates X-Y-Z are added to the diagrams to facilitate intuitive reading and comprehension. Please refer to FIG. 1. The electronic device 100 is, for example, a charging station, which may be installed in an indoor car park or an outdoor car park. Moreover, the charging station may be configured to charge an electric vehicle, which is not limited by the disclosure.

Please refer to FIGS. 2, 3, 4, and 5. The electronic device 100 includes a housing 110, a heat conductive portion 120, a circuit board 130, a fin set 140, and a fan 150. The housing 110 has an accommodating space 112. As shown in FIG. 4, the heat conductive portion 120 is disposed in the accommodating space 112, and divides the accommodating space 112 into a first space A1 (the space where the heat conductive portion 120 faces the negative Y-axis direction in FIG. 4) and a second space A2 (the space where the heat conductive portion 120 faces the positive Y-axis direction in FIG. 4) opposite to each other. The circuit board 130 is disposed in the first space A1, and includes a heat source 131. The heat source 131 may be any electronic element, which is not limited by the disclosure. The heat source 131 is thermally coupled to the heat conductive portion 120 and located between the circuit board 130 and the heat conductive portion 120. The fin set 140 is disposed in the second space A2 and thermally coupled to the heat conductive portion 120. The fan 150 is disposed in the second space A2 and located on one side of the fin set 140.

In this way, the heat generated by the heat source 131 can be transferred to the fin set 140 through the heat conductive portion 120, and then the fan 150 guides the airflow through the fin set 140 to discharge the heat from the housing 110, thereby providing excellent heat dissipation efficiency.

In addition, the circuit board 130 and the heat source 131 are located in the first space A1, and the fin set 140 and the fan 150 are located in the second space A2. In other words, the heat conductive portion 120 isolates the circuit board 130 and the heat source 131 from the fin set 140, so the dust entering the fin set 140 with the airflow of the fan 150 is isolated in the second space A2. In this way, dust is prevented from entering the first space A1, adhering to the circuit board 130 and the heat source 131, and causing the circuit board 130 to be non-conductive, thereby providing an excellent dustproof effect.

Moreover, the electronic device 100 may further include a heat conductive medium 160. The heat conductive medium 160 is disposed between the heat source 131 and the heat conductive portion 120 to increase the heat conduction efficiency of the heat source 131 and the heat conductive portion 120. The heat conductive medium 160 may be made of aluminum oxide, copper, ceramic sheets, thermal paste, or other high thermal conductivity materials. However, the disclosure is not limited thereto.

In the embodiment, the housing 110 includes a casing 111 and a frame 113. The frame 113 is disposed in the casing 111, and may be made of aluminum alloy to provide a better heat conduction effect. However, the disclosure is not limited thereto. The heat conductive portion 120 and the fin set 140 are connected to the frame 113, respectively. Preferably, the heat conductive portion 120 and the fin set 140 are integrally formed, and may be made of aluminum alloy to provide a better heat conduction effect. However, the disclosure is not limited thereto.

In other embodiments, the frame, the heat conductive portion, and the fin set may be formed by combining different components.

For ease of description, as shown in FIG. 5, the housing 110 includes a first side B1 (that is, the side of the fin set 140 facing the positive Z-axis direction, or the upper side), a second side B2 (that is, the side of the fin set 140 facing the positive X-axis direction, or the left side), a third side B3 (that is, the side of the fin set 140 facing the negative X-axis direction, or the right side), and a fourth side B4 (that is, the side of the fin set 140 facing the negative Z-axis direction, or the bottom side).

Please refer to FIGS. 3 and 5. The frame 113 includes a first wall 113a, a second wall 113b, a third wall 113c, a fourth wall 113d, and a fifth wall 113e. The first wall 113a, the second wall 113b, the third wall 113c, and the fourth wall 113d are connected circumferentially in sequence. The first wall 113a, the second wall 113b, the third wall 113c, the fourth wall 113d, and the heat conductive portion 120 collectively surround the first space A1. Moreover, the first wall 113a, the second wall 113b, the third wall 113c, the fourth wall 113d, the fifth wall 113e, and the heat conductive portion 120 collectively surround the second space A2.

As shown in FIG. 5, the housing 110 further has an air inlet 111a and an air outlet 111b disposed on the casing 111, and the number of the air inlets 111a and/or the air outlets 111b may be one or more. The air inlet 111a is located on the second side B2 of the housing 110, and the air outlet 111b is located on the third side B3 of the housing 110. The fin set 140 is located between the air inlet 111a and the air outlet 111b, and the air inlet 111a and the air outlet 111b are aligned with the fin set 140. The fan 150 is disposed on the second wall 113b of the housing 110, close to the second side B2 of the housing 110, and aligned with the air inlet 111a. The fin set 140 has multiple fins 141, and multiple airflow channels C are respectively formed between any two adjacent fins 141. Moreover, these airflow channels C communicate with the air inlet 111a and the air outlet 111b. In the embodiment, the shape of the airflow channel C is straight. However, the disclosure is not limited thereto. The airflow sequentially enters the airflow channels C between the fins 141 from the second side B2 of the housing 110 through the air inlet 111a, and finally passes through the air outlet 111b from the airflow channel C in the negative X-axis direction to discharge the heat on the fins 141 from the housing 110. In other words, the air inlet 111a and the air outlet 111b are disposed on both sides of the housing 110, respectively, so the first side B1 (that is, the top side) of the housing 110 does not have any openings, which may further prevent dust and water from entering the housing, and may increase the dustproof and waterproof effects of the electronic device 100. Thus, the electronic device 100 may be adapted for various environments, whether indoor or outdoor.

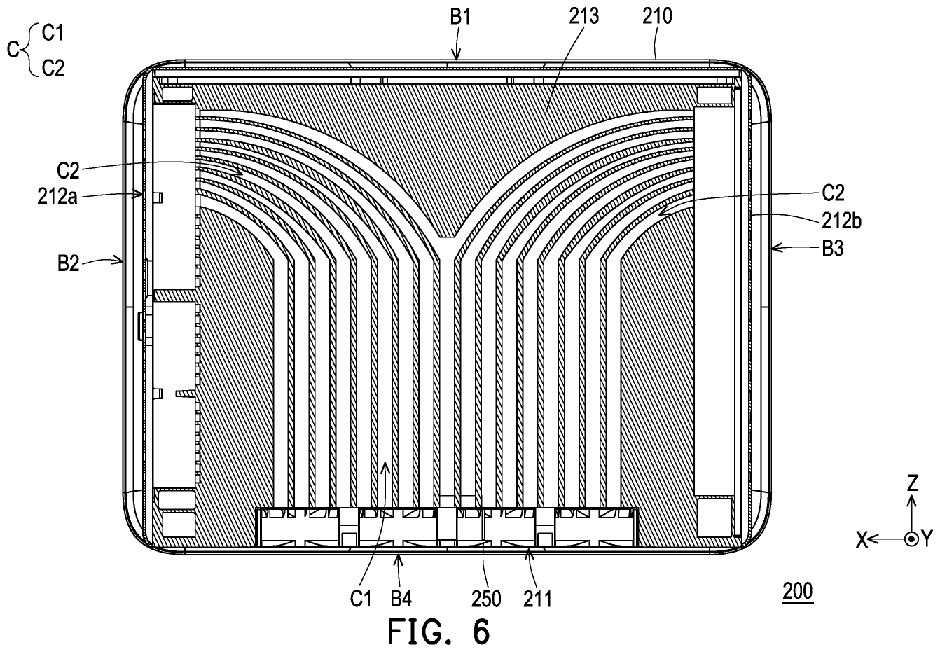

FIG. 6 is a schematic view of an electronic device according to another embodiment of the disclosure. As shown in FIG. 6, in the electronic device 200 of the embodiment, an air inlet 211 is located on the fourth side B4 of a housing 210 (that is, the bottom side in FIG. 6). The number of the air outlets may be more than one (for example, an air outlet 212a and an air outlet 212b), and the air outlet 212a and the air outlet 212b are located on the second side B2 and the third side B3, of the housing 210, respectively. Moreover, the air outlet 212a and the air outlet 212b are aligned with the fin set. In other words, the air outlet 212a and the air outlet 212b are respectively located on a different side adjacent to the bottom side of the housing 210. The fan 250 is disposed on the bottom side of the frame 213. The airflow channel C includes a straight first airflow section C1 and an arc-shaped second airflow section C2. The first airflow section C1 is aligned with the air inlet 211, and the second airflow section C2 is aligned with the air outlet 212a and the air outlet 212b. In the embodiment, since the first side B1 (that is, the top side) of the housing 210 does not have any openings, dust and water may be further prevented from entering the housing 210, and the dustproof and waterproof effects of the electronic device 200 are increased. Thus, the electronic device 200 may be adapted for various environments, whether indoor or outdoor.

In summary, in the electronic device of the disclosure, the heat generated by the heat source is transferred to the fin set through the heat conductive portion, and then the fan guides the airflow through the fin set to discharge the heat from the housing, thereby providing excellent heat dissipation efficiency. In addition, since the heat conductive portion isolates the circuit board from the fin set, the dust entering the fin set with the airflow of the fan will not adhere to the circuit board and the heat source, thereby providing an excellent dustproof effect.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. An electronic device, comprising:
a housing having an accommodating space;
a heat conductive portion disposed in the accommodating space and dividing the accommodating space into a first space and a second space;
a circuit board disposed in the first space and containing a heat source, wherein the heat source generates heat and is thermally coupled to the heat conductive portion;
a fin set disposed in the second space and thermally coupled to the heat conductive portion; and
a fan disposed in the second space and located on one side of the fin set, wherein the fan is adapted for guiding an airflow through the fin set to discharge the heat generated by the heat source from the housing.

2. The electronic device according to claim 1, wherein the housing comprises:
a casing; and
a frame disposed in the casing and connected to the heat conductive portion and the fin set.

3. The electronic device according to claim 2, wherein a material of the frame comprises aluminum alloy.

4. The electronic device according to claim 2, wherein the heat conductive portion, the fin set, and the frame are integrally formed.

5. The electronic device according to claim 1, wherein a material of the heat conductive portion and the fin set comprises aluminum alloy.

6. The electronic device according to claim 1, wherein the housing has an air inlet and an air outlet, the fan is aligned with the air inlet, the air inlet and the air outlet are located on opposite sides of the housing, respectively, and the fin set is located between the air inlet and the air outlet.

7. The electronic device according to claim 1, wherein the housing has an air inlet and an air outlet, the fan is aligned with the air inlet located on a bottom side of the housing, the air outlet is located on one side adjacent to the bottom side of the housing, and the fin set is located between the air inlet and the air outlet.

8. The electronic device according to claim 1, wherein the housing has an air inlet and an air outlet, the fin set has a plurality of fins, a plurality of airflow channels are respectively formed between any two adjacent ones of the plurality of fins, and the plurality of airflow channels communicate with the air inlet and the air outlet.

9. The electronic device according to claim 8, wherein a shape of each of the plurality of airflow channels comprises a straight line, an arc, or a combination of the straight line and the arc.

10. The electronic device according to claim 1, further comprising a heat conductive medium disposed in the second space and located between the heat source and the heat conductive portion.
